(19) United States
(12) Patent Application Publication
(10) Pub. No.: US 2026/0020216 A1
(43) Pub. Date: Jan. 15, 2026

(54) SEMICONDUCTOR DEVICE AND METHOD OF MANUFACTURING THE SAME

(71) Applicant: Samsung Electronics Co., Ltd., Suwon-si (KR)

(72) Inventors: Hyeonwoo JEONG, Suwon-si (KR); Hyeri AN, Suwon-si (KR); Seonghyuk CHO, Suwon-si (KR); Yongseok LEE, Suwon-si (KR); Jaesung LEE, Suwon-si (KR); Hoouk LEE, Suwon-si (KR); Juyoung HUH, Suwon-si (KR)

(73) Assignee: Samsung Electronics Co., Ltd., Suwon-si (KR)

(21) Appl. No.: 19/023,787

(22) Filed: Jan. 16, 2025

(30) Foreign Application Priority Data
Jul. 9, 2024 (KR) 10-2024-0090674

(51) Int. Cl. H10B 12/00; H01L 21/311

(52) U.S. Cl. CPC H10B 12/03; H01L 21/31116; H01L 21/31144

(57) ABSTRACT

A method of manufacturing a semiconductor device may include sequentially forming a word line filling a word line trench of a substrate and a buried insulation layer on the word line, performing a first etching process of forming a logic active region contact hole extending to an inner portion of a logic active region of the substrate and a word line contact hole extending to an inner portion of the buried insulation layer, and performing a second etching process so that the word line contact hole extends to an inner portion of the word line. The first etching process may be performed using a first etching gas, which may include difluoromethane (CH₂F₂) and octafluorobutyne (C₄F₈) and where a ratio of difluoromethane to octafluorobutyne may be at least 1:1.5. The first etching gas may react with the logic active region to form a barrier layer.

### CROSS-REFERENCE TO RELATED APPLICATION

This application is based on and claims priority under 35 U.S.C. § 119 to Korean Patent Application No. 10-2024-0090674, filed on Jul. 9, 2024 in the Korean Intellectual Property Office, the disclosure of which is incorporated by reference herein in its entirety.

### BACKGROUND

Inventive concepts relate to a semiconductor device and/or a method of manufacturing the same, and more particularly, to a semiconductor device which includes contact plugs electrically connecting different vertical levels with each other and/or a method of manufacturing the same.

As the electronics industry advances rapidly and the demands of users increase, electronic devices are being miniaturized further and becoming more multifunctional. Therefore, semiconductor devices used in electronic devices may need a higher degree of integration, and thus, the design rule of elements of semiconductor devices may be reduced. Due to this, it may be difficult to secure the reliability of electrical connections between elements of semiconductor devices.

### SUMMARY

Inventive concepts provide a semiconductor device where the reliability of electrical connections may be improved and/or a method of manufacturing the semiconductor device.

According to an example embodiment, a method of manufacturing a semiconductor device may include sequentially forming a word line filling a word line trench of a substrate and a buried insulation layer on the word line; performing a first etching process, the first etching process including forming a logic active region contact hole extending to an inner portion of a logic active region of the substrate and forming a word line contact hole extending to an inner portion of the buried insulation layer; and performing a second etching process so that the word line contact hole passes through the buried insulation layer and extends to an inner portion of the word line. The first etching process may be performed using a first etching gas. The first etching gas may include difluoromethane (CH₂F₂) and octafluorobutyne (C₄F₈), where a ratio of difluoromethane to octafluorobutyne in the first etching gas may be at least 1:1.5. The logic active region contact hole may expose the logic active region of the substrate to provide an exposed logic active region of the substrate. The first etching process may include forming a barrier layer on the exposed logic active region of the substrate, the barrier layer being formed from the first etching gas reacting with a material of the substrate in the logic active region of the substrate that is exposed by the logic active region contact hole while the first etching process is performed.

According to an example embodiment, a method of manufacturing a semiconductor device may include sequentially forming a word line filling a word line trench of a substrate and a buried insulation layer on the word line, the word line including an upper word line layer and a lower word line layer; performing a first etching process, the first etching process including forming a logic active region contact hole extending to an inner portion of a logic active region of the substrate and a word line contact hole extending to an inner portion of the buried insulation layer; performing a second etching process so that the word line contact hole passes through the buried insulation layer and extends to an inner portion of the upper word line layer; and performing a third etching process so that the word line contact hole passes through the upper word line layer and extends to an inner portion of the lower word line layer. The first etching process may be performed using a first etching gas. The first etching gas may include difluoromethane (CH₂F₂) and octafluorobutyne (C₄F₈), where a ratio of difluoromethane to octafluorobutyne in the first etching gas may be at least 1:1.5. The logic active region contact hole may expose the logic active region of the substrate to provide an exposed logic active region of the substrate. The first etching process may include forming a barrier layer on the exposed logic active region of the substrate, the barrier layer being formed from the first etching gas reacting with a material of the substrate in the logic active region of the substrate that is exposed by the logic active region contact hole while the first etching process is being performed.

According to an example embodiment, a method of manufacturing a semiconductor device may include sequentially forming a word line filling a word line trench of a substrate and a buried insulation layer on the word line, the word line including an upper word line layer and a lower word line layer; forming a plurality of bit line contact holes extending to an inner portion of an active region of the substrate; forming a plurality of bit line structures respectively filling the plurality of bit line contact holes; forming a spacer structure covering a sidewall of each of the plurality of bit line structures; forming a buried contact hole between two adjacent bit line structures of the plurality of bit line structures such that a plurality of buried contact holes are formed; forming a plurality of buried contacts filling the plurality of buried contact holes; forming a plurality of insulation fences between the spacer structure and the plurality of buried contacts; forming a logic active region contact hole extending to an inner portion of a logic active region of the substrate and a word line contact hole passing through the buried insulation layer and extending to an inner portion of the word line; forming a logic active region contact plug filling the logic active region contact hole, a word line contact plug filling the word line contact hole, and a landing pad filling a landing pad hole defined by the spacer structure and a corresponding insulation fence among the plurality of insulating fences; and forming a capacitor structure on the landing pad. The forming the logic active region contact hole and the word line contact hole may include performing a first etching process including forming a logic active region contact hole extending to an inner portion of a logic active region of the substrate and a word line contact hole extending to an inner portion of the buried insulation layer, performing a second etching process so that the word line contact hole passes through the buried insulation layer and extends to an inner portion of the upper word line layer, and performing a third etching process so that the word line contact hole passes through the upper word line layer and extends to an inner portion of the lower word line layer. The first etching process may be performed using a first etching gas. The first etching gas may include difluoromethane (CH₂F₂) and octafluorobutyne (C₄F₈), where a ratio of difluoromethane to octafluorobutyne may be at least 1:1.5. The logic active region contact hole may expose the logic active region of the substrate to provide an exposed logic active region of the substrate. The first etching process may include forming a barrier layer on the exposed logic active region of the substrate. The barrier layer may be formed from the first etching gas reacting with a material of the substrate in the logic active region that is exposed by the logic active region contact hole while the first etching process is being performed. The plurality of buried contact holes may be defined by the spacer structure and upper surfaces of the plurality of active regions

### BRIEF DESCRIPTION OF THE DRAWINGS

Embodiments will be more clearly understood from the following detailed description taken in conjunction with the accompanying drawings in which:

FIG. 1 is a plan layout view schematically illustrating elements of a semiconductor device according to embodiments;

FIGS. 2A, 2B, 2C, and 2D are cross-sectional views illustrating a semiconductor device according to embodiments; and

FIGS. 3A to 3D, 4A to 4D, 5A to 5D, 6A to 6D, 7A to 7D, 8A to 8D, and 9A to 9D are cross-sectional views to describe a method of manufacturing a semiconductor device, according to embodiments.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, example embodiments will be described in detail with reference to the accompanying drawings. Like reference numerals refer to like elements in the drawings, and their repeated descriptions are omitted.

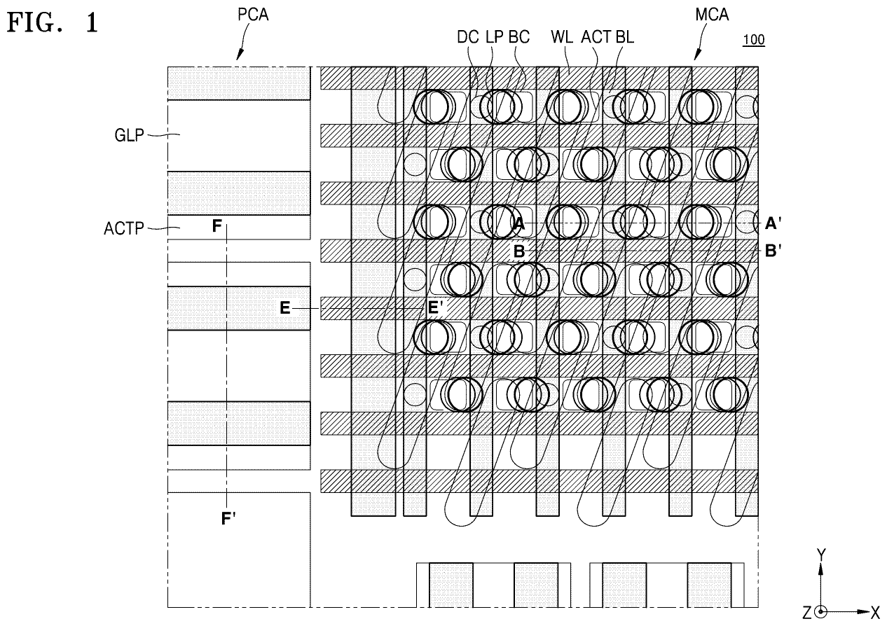

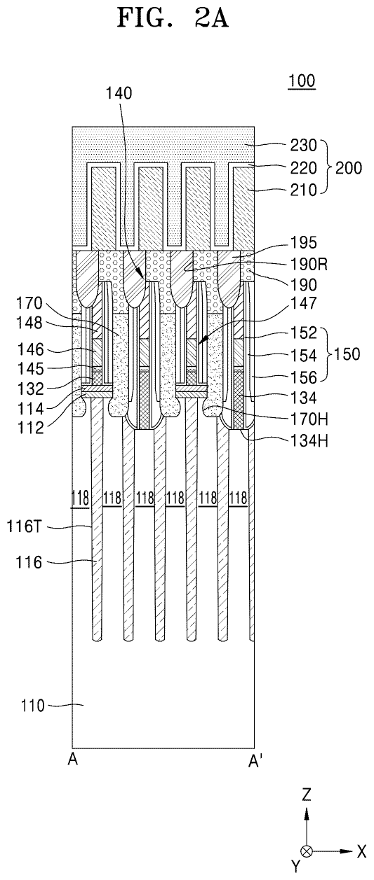

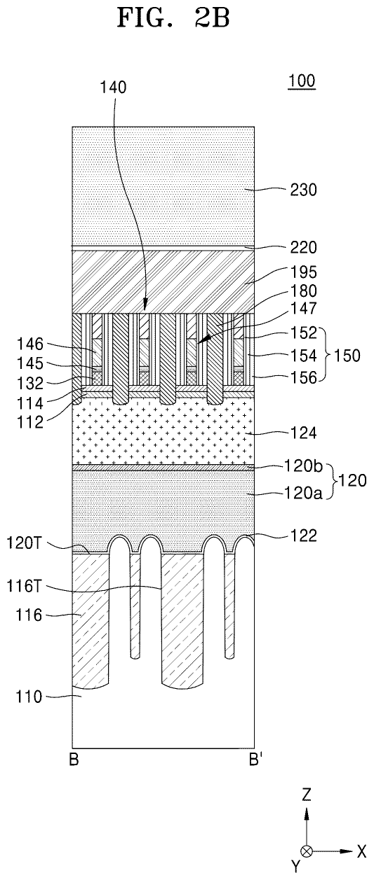

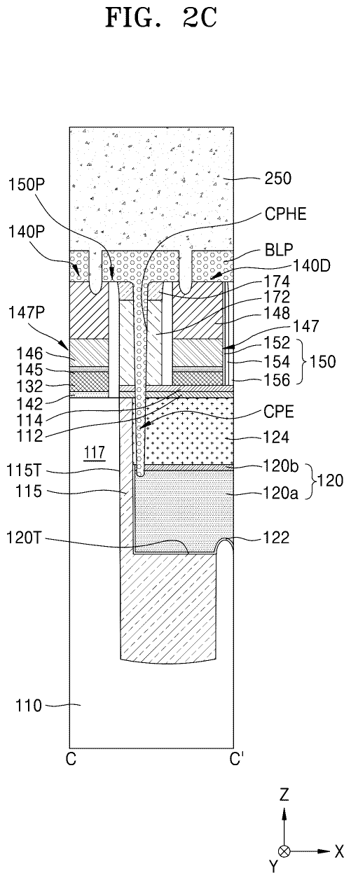

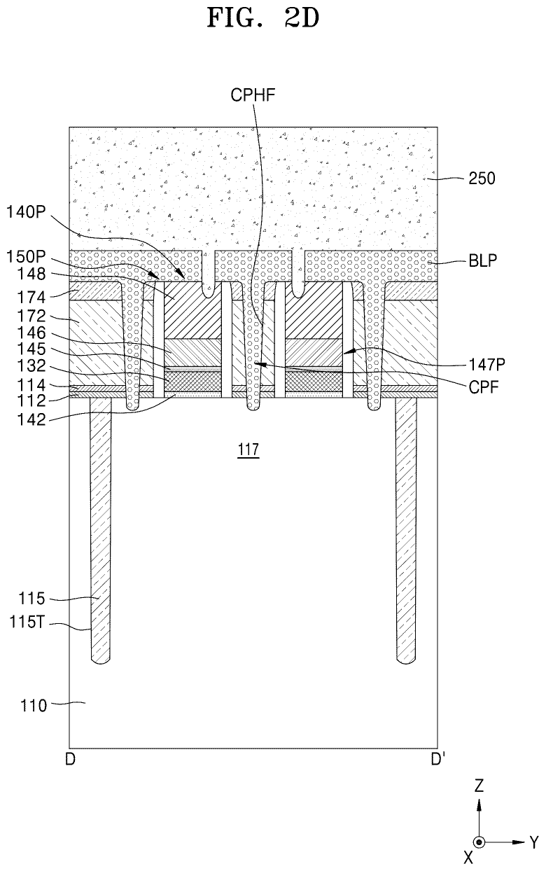

FIG. 1 is a plan layout view schematically illustrating elements of a semiconductor device 100 according to embodiments. FIGS. 2A, 2B, 2C, and 2D are cross-sectional views illustrating the semiconductor device 100 according to embodiments. In detail, FIG. 2A is a cross-sectional view taken along line A-A′ of FIG. 1, FIG. 2B is a cross-sectional view taken along line B-B′ of FIG. 1, FIG. 2C is a cross-sectional view taken along line C-C′ of FIG. 1, and FIG. 2D is a cross-sectional view taken along line D-D′ of FIG. 1.

Referring to FIG. 1, the semiconductor device 100 may include a memory cell area MCA and a peripheral circuit area PCA. A plurality of active regions ACT may be formed in the memory cell area MCA, and a plurality of logic active regions ACTP may be formed in the peripheral circuit area PCA.

In embodiments, each of the plurality of active regions ACT formed in the memory cell area MCA may be disposed to have a long axis in an inclined diagonal direction with respect to a first horizontal direction (an X direction) and a second horizontal direction (a Y direction).

A plurality of word lines WL may extend in parallel in the first horizontal direction (the X direction) across the plurality of active regions ACT. A plurality of bit lines BL may extend in parallel in the second horizontal direction (the Y direction) on the plurality of word lines WL. The plurality of bit lines BL may be connected to the plurality of active regions ACT through a bit line contact DC.

A plurality of buried contacts BC may be formed between two adjacent bit lines BL of the plurality of bit lines BL. In embodiments, the plurality of buried contacts BC may be arranged in one row in each of the first horizontal direction (the X direction) and the second horizontal direction (the Y direction). A plurality of landing pads LP may be formed on the plurality of buried contacts BC. The plurality of buried contacts BC and the plurality of landing pads LP may electrically connect the active region ACT to a lower electrode 210 (see FIG. 2A) of a capacitor structure 200 (see FIG. 2A) formed on the plurality of bit lines BL. Each of the plurality of landing pads LP may be disposed to at least partially overlap the buried contact BC and the bit line BL in a vertical direction (a Z direction).

A plurality of gate line patterns GLP may be disposed on the logic active region ACTP, in the peripheral circuit area PCA. In embodiments, some of a plurality of gate line patterns GLP may extend in parallel in the first horizontal direction (the X direction) on the logic active region ACTP, and the other plurality of gate line patterns GLP may extend in parallel in the second horizontal direction (the Y direction) on the logic active region ACTP, but inventive concepts are not limited thereto. For example, each of the plurality of gate line patterns GLP may have various widths, may have a flexure, or may vary in width, and may extend in various horizontal directions.

In FIG. 1, the other elements, except the plurality of logic active regions ACTP and the plurality of gate line patterns GLP, of the peripheral circuit area PCA are omitted for convenience of the illustration. Also, in FIG. 1, it is illustrated that the plurality of gate line patterns GLP are disposed on only the plurality of logic active regions ACTP, but inventive concepts are not limited thereto. For example, at least some of the plurality of gate line patterns GLP may extend to the outside of the logic active region ACTP, namely, a logic device isolation layer 115 (see FIGS. 2C and 2D).

The plurality of gate line patterns GLP may be formed at the same level as the plurality of bit lines BL. In embodiments, the plurality of gate line patterns GLP and the plurality of bit lines BL may include the same material, or at least a portion of each of the plurality of gate line patterns GLP and at least a portion of each of the plurality of bit lines BL may include the same material. For example, a process of forming all or some of the plurality of gate line patterns GLP and all or a portion of a process of forming the plurality of bit lines BL may be the same process.

Referring to FIGS. 2A to 2D, the semiconductor device 100 may include a substrate 110 including the peripheral circuit area PCA and the memory cell area MCA. The substrate 110 may include silicon (for example, single crystalline silicon, polycrystalline silicon, or amorphous silicon). In embodiments, the substrate 110 may include at least one selected from among germanium (Ge), silicon germanium (SiGe), silicon carbide (SiC), gallium arsenide (GaAs), indium arsenide (InAs), and indium phosphide (InP). In embodiments, the substrate 110 may include a conductive region, and for example, may include an impurity-doped well or an impurity-doped structure.

A device isolation layer 116 and a logic device isolation layer 115 may be formed in the substrate 110. Each of the device isolation layer 116 and the logic device isolation layer 115 may include oxide, nitride, or a combination thereof. A plurality of active regions 118 may be defined in the substrate 110 by the device isolation layer 116, in the memory cell area MCA (see FIG. 1), and a plurality of logic active regions 117 may be defined in the substrate 110 by the logic device isolation layer 115, in the peripheral circuit area PCA (see FIG. 1). Here, the plurality of active regions 118 may correspond to the plurality of active regions ACT of FIG. 1, and the plurality of logic active regions 117 may correspond to the plurality of logic active regions ACTP of FIG. 1. The device isolation layer 116 and the logic device isolation layer 115 may not be clearly differentiated from each other at a boundary portion between the memory cell area MCA and the peripheral circuit area PCA.

In embodiments, each of the plurality of active regions 118 may have a relatively long island shape which has a short axis and a long axis one-dimensionally as in the active region ACT illustrated in FIG. 1, and each of the plurality of logic active regions 117 may one-dimensionally have a rectangular shape as in the logic active region ACTP illustrated in FIG. 1, but inventive concepts are not limited thereto.

A plurality of word line trenches 120T may be formed in the substrate 110. The plurality of word line trenches 120T may extend in parallel in the first horizontal direction (the X direction), and each of the plurality of word line trenches 120T may have a line shape which is arranged to have an equal interval in the second horizontal direction (the Y direction) across the active region 118. In embodiments, a step height may be formed in lower surfaces of the plurality of word line trenches 120T.

A plurality of gate dielectric layers 122, a plurality of word lines 120, and a plurality of buried insulation layers 124 may be sequentially arranged in the plurality of word line trenches 120T. The plurality of word lines 120 may configure the plurality of word lines WL illustrated in FIG. 1. The plurality of word lines 120 may extend in parallel in the first horizontal direction (the X direction), and each of the plurality of word lines 120 may have a line shape which is arranged to have an equal interval in the second horizontal direction (the Y direction) across the active region 118. An upper surface of each of the plurality of word lines 120 may be disposed at a vertical level which is lower than an upper surface of the substrate 110.

Each of the plurality of word lines 120 may include a lower word line layer 120a and an upper word line layer 120b. The lower word line layer 120a may include, for example, a metal material, conductive metal nitride, or a combination thereof. For example, the lower word line layer 120a may include titanium (Ti), titanium nitride (TiN), tantalum (Ta), tantalum nitride (TaN), tungsten (W), tungsten nitride (WN), titanium silicon nitride (TiSiN), tungsten silicon nitride (WSiN), or a combination thereof. The upper word line layer 120b may include, for example, doped polysilicon.

The gate dielectric layer 122 may include at least one selected from among silicon oxide, silicon nitride, silicon oxynitride, oxide/nitride/oxide (ONO), and a high-k dielectric film having a dielectric constant which is higher than that of silicon oxide. For example, the gate dielectric layer 122 may have a dielectric constant of about 10 to about 25. For example, the gate dielectric layer 122 may include at least one material selected from among hafnium oxide (HfO), hafnium silicate (HfSiO), hafnium oxide nitride (HfON), hafnium silicon oxide nitride (HfSiON), lanthanum oxide (LaO), lanthanum aluminum oxide (LaAlO), zirconium oxide (ZrO), zirconium silicon oxide (ZrSiO), zirconium oxide nitride (ZrON), zirconium silicon oxide nitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric layer 122 may include HfO₂, Al₂O₃, HfAlO₃, Ta₂O₃, or TiO₂.

An upper surface of each of the plurality of buried insulation layers 124 may be disposed at substantially the same vertical level as the upper surface of the substrate 110. Each of the buried insulation layers 124 may include at least one material film selected from a silicon oxide film, a silicon nitride film, a silicon oxynitride film, and a combination thereof.

A first insulation layer pattern 112 and a second insulation layer pattern 114 may be sequentially disposed on the device isolation layer 116, the plurality of active regions 118, the plurality of buried insulation layers 124, the logic device isolation layer 115, and the plurality of logic active regions 117. Each of the first insulation layer pattern 112 and a second insulation layer pattern 114 may include silicon oxide, silicon oxynitride, or silicon nitride.

A plurality of bit line contact holes 134H may pass through the first insulation layer pattern 112 and the second insulation layer pattern 114 and may extend to an inner portion of the substrate 110, and a plurality of bit line contacts 134 may be disposed in the plurality of bit line contact holes 134H. The plurality of bit line contacts 134 may be connected to the plurality of active regions 118. The plurality of bit line contacts 134 may include silicon (Si), germanium (Ge), tungsten (W), tungsten nitride (WN), cobalt (Co), nickel (Ni), aluminum (Al), molybdenum (Mo), ruthenium (Ru), titanium (Ti), titanium nitride (TiN), tantalum (Ta), tantalum nitride (TaN), copper (Cu), or a combination thereof. The plurality of bit line contacts 134 may correspond to the bit line contact DC illustrated in FIG. 1.

A plurality of bit lines 147 may extend lengthwise in the second horizontal direction (the Y direction) on the substrate 110 and the plurality of bit line contacts 134. Each of the plurality of bit lines 147 may be connected to the active region 118 through the bit line contact 134. The plurality of bit lines 147 may correspond to the bit line BL illustrated in FIG. 1.

In embodiments, each of the plurality of bit lines 147 may include a lower conductive layer 132, a middle conductive layer 145, and an upper conductive layer 146.

The lower conductive layer 132 may extend in the second horizontal direction (the Y direction) on the second insulation layer pattern 114. The lower conductive layer 132 may include Si, Ge, W, WN, Co, Ni, Al, Mo, Ru, Ti, TiN, Ta, TaN, Cu, or at least one of cobalt silicide, nickel silicide, and tungsten silicide.

Each of the middle conductive layer 145 and the upper conductive layer 146 may be disposed on an upper surface of the lower conductive layer 132 and may extend in the second horizontal direction (the Y direction). In embodiments, each of the middle conductive layer 145 and the upper conductive layer 146 may include one of W, Ru, Mo, Ti, rhodium (Ro), iridium (Ir), and an alloy thereof.

A plurality of bit line capping lines 148 may be respectively disposed on the plurality of bit lines 147. Each of the plurality of bit line capping lines 148 may include at least one of silicon nitride, silicon oxide, and silicon oxynitride. Each of the plurality of bit lines 147 and the plurality of bit line capping lines 148 respectively disposed on the plurality of bit lines 147 may configure a plurality of bit line structures 140.

A spacer structure 150 may be disposed on both sidewalls of each of the plurality of bit lines 147 and the plurality of bit line capping lines 148 disposed on the plurality of bit lines 147. The spacer structure 150 may include a first spacer 152, a second spacer 154, and a third spacer 156.

The first spacer 152 may cover a sidewall of the bit line 147, a sidewall of the bit line capping line 148, and a sidewall of the bit line contact 134 and may cover an inner wall of the bit line contact hole 134H. The first spacer 152 may extend in the second horizontal direction (the Y direction). In embodiments, the first spacer 152 may include silicon nitride.

The second spacer 154 may be disposed on a sidewall of the first spacer 152. The second spacer 154 may extend in the second horizontal direction (the Y direction) on the sidewall of the first spacer 152. In embodiments, the second spacer 154 may include silicon oxide.

The third spacer 156 may be disposed on a sidewall of the second spacer 154. The third spacer 156 may extend in the second horizontal direction (the Y direction) on the sidewall of the second spacer 154. In embodiments, the third spacer 156 may include silicon nitride.

A plurality of gate line structures 140P may be disposed on the logic active region 117. In embodiments, at least one dummy bit line structure 140D may be disposed between the bit line 147 and the gate line structure 140P.

The gate line structure 140P may include a gate line 147P and an insulation capping line 148 covering the gate line 147P. A plurality of gate lines 147P included in the plurality of gate line structures 140P may be formed along with the plurality of bit lines 147. That is, similar to the plurality of bit lines 147, the gate line 147P may include a lower conductive layer 132, a middle conductive layer 145, and an upper conductive layer 146.

A gate insulation layer pattern 142 may be disposed between the gate line 147P and the logic active region 117. The plurality of gate lines 147P may correspond to the plurality of gate line patterns GLP illustrated in FIG. 1.

A sidewall of the gate line structure 140P may be covered by a gate insulation spacer 150P. The gate insulation spacer 150P may include, for example, nitride.

A plurality of buried contact holes 170H may be formed between two adjacent bit lines BL of the plurality of bit lines BL. The plurality of buried contact holes 170H may include an internal space which is defined by the active region 118 and the spacer structure 150 covering a sidewall of each of two adjacent bit lines 147 between the two adjacent bit lines 147 of the plurality of bit lines 147. A plurality of buried contacts 170 may be respectively disposed in the plurality of buried contact holes 170H. A bottom portion and a sidewall lower portion of each of the plurality of buried contacts 170 may contact the active region 118. In embodiments, the plurality of buried contacts 170 may include doped polysilicon. The plurality of buried contacts 170 may correspond to the buried contact BC illustrated in FIG. 1.

A plurality of insulation fences 180 may be disposed in the second horizontal direction (the Y direction) between two adjacent bit lines BL. In a one-dimensional viewpoint, the plurality of buried contacts 170 and the plurality of insulation fences 180 may be alternately arranged between two bit lines BL extending in the second horizontal direction (the Y direction). In embodiments, the plurality of insulation fences 180 may include nitride.

A plurality of landing pads 190 may be respectively disposed on the plurality of buried contacts 170. The plurality of landing pads 190 may each include a conductive barrier layer (not shown) and a landing pad conductive layer (not shown). The conductive barrier layer may include Ti, TiN, or a combination thereof, and the landing pad conductive layer may include metal, metal nitride, conductive polysilicon, or a combination thereof. For example, the landing pad conductive layer may include W. The plurality of landing pads 190 may one-dimensionally have a plurality of island pattern shapes. The plurality of landing pads 190 may correspond to the landing pad LP illustrated in FIG. 1.

The plurality of landing pads 190 may be spaced apart from one another by an insulation pattern 195 formed in a recess portion 190R. The insulation pattern 195 may electrically insulate the plurality of landing pads 190 from one another. The insulation pattern 195 may include at least one of silicon nitride, silicon oxide, and silicon oxynitride.

In the logic active region 118, a first interlayer insulation layer 172 and a second interlayer insulation layer 174 may be sequentially arranged on the first insulation layer pattern 112 and the second insulation layer pattern 114 each adjacent to the plurality of gate line structures 140P. The first interlayer insulation layer 172 may include oxide, and the second interlayer insulation layer 174 may include nitride. An upper surface of the second interlayer insulation layer 174 and an upper surface of the gate line structure 140P may be disposed at the same vertical level.

The word line contact hole CPHE may pass through the first insulation layer pattern 112, the second insulation layer pattern 114, the first interlayer insulation layer 172, the second interlayer insulation layer 174, the buried insulation layer 124, and the upper word line layer 120b and may extend to an inner portion of the lower word line layer 120a. A word line contact plug CPE may be disposed in the word line contact hole CPHE. The word line contact plug CPE may contact the upper word line layer 120b and the lower word line layer 120a at a lower end portion of the word line contact plug CPE.

A logic active region contact hole CPHF may pass through the first insulation layer pattern 112, the second insulation layer pattern 114, the first interlayer insulation layer 172, and the second interlayer insulation layer 174 and may extend to an inner portion of the logic active region 117. A logic active region contact plug CPF may be disposed in the logic active region contact hole CPHF. The logic active region contact plug CPF may contact the logic active region 117 at a lower end portion of the logic active region contact plug CPF.

A plurality of logic bit lines BLP may be disposed on the second interlayer insulation layer 174. Each of the plurality of logic bit lines BLP may be connected to the logic active region contact plug CPF and the word line contact plug CPE, on the logic active region 117.

A capacitor structure 200 may be disposed on the plurality of landing pads 190 and the insulation pattern 195. The capacitor structure 200 may include a lower electrode 210, a capacitor dielectric layer 220, and an upper electrode 230. The lower electrode 210 may be disposed so that a bottom portion of the lower electrode 210 is disposed on the landing pad 190. The lower electrode 210 may be electrically connected to a landing pad 190 corresponding to the lower electrode 210. The capacitor dielectric layer 220 may be disposed with a thin thickness to conformally cover the lower electrode 210, and the upper electrode 230 may be disposed on the capacitor dielectric layer 220.

In embodiments, each of the plurality of lower electrodes 210 may have a pillar shape. In other embodiments, each of the plurality of lower electrodes 210 may have a cylinder shape where a lower portion is closed. In embodiments, the plurality of lower electrodes 210 may be arranged in a honeycomb shape arranged in zigzag with respect to the first horizontal direction (the X direction) or the second horizontal direction (the Y direction). In other embodiments, the plurality of lower electrodes 210 may be arranged in a matrix form arranged in one row in each of the first horizontal direction (the X direction) and the second horizontal direction (the Y direction). The plurality of lower electrodes 210 may include, for example, doped silicon, metal such as tungsten or copper, or a conductive metal compound such as titanium nitride.

The capacitor dielectric layer 220 may include, for example, TaO, TaAlO, TaON, AlO, AlSiO, HfO, HfSiO, ZrO, ZrSiO, TiO, TiAlO, BST((Ba,Sr)TiO), STO(SrTiO), BTO(BaTiO), PZT(Pb(Zr,Ti)O), (Pb,La)(Zr,Ti)O, Ba(Zr,Ti)O, Sr(Zr,Ti)O, or a combination thereof.

The upper electrode 230 may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof.

A buried insulation layer 250 may be filled on the plurality of logic bit lines BLP corresponding to a vertical level at which the plurality of capacitor structures 200 are disposed. The buried insulation layer 250 may include, for example, an oxide film or an ultra-low K (ULK) film. The oxide film may include one film selected from among boro-phospho-silicate glass (BPSG), phosphosilicate glass (PSG), boro-silicate glass (BSG), un-doped silicate glass (USG), tetra ethyl ortho silicate (TEOS), and high density plasma (HDP) films. The ULK film may include, for example, one film selected from among a SiOC film and a SiCOH film each having an ultra-low dielectric constant K of about 2.2 to about 2.4.

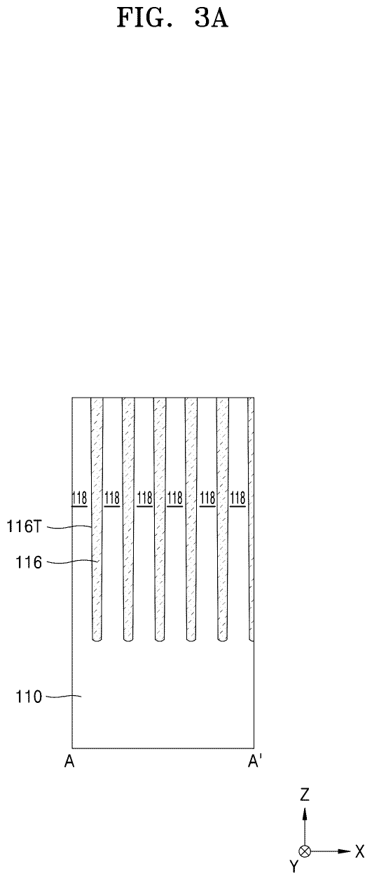

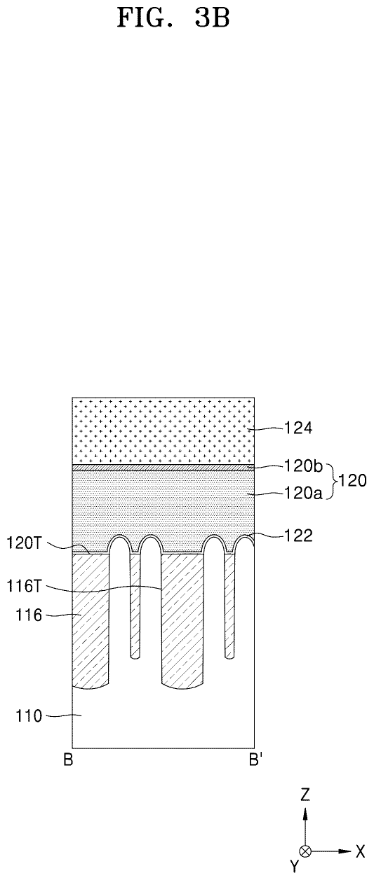

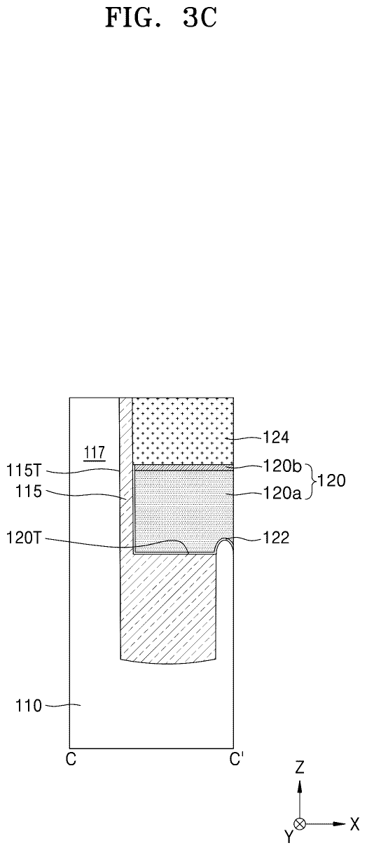

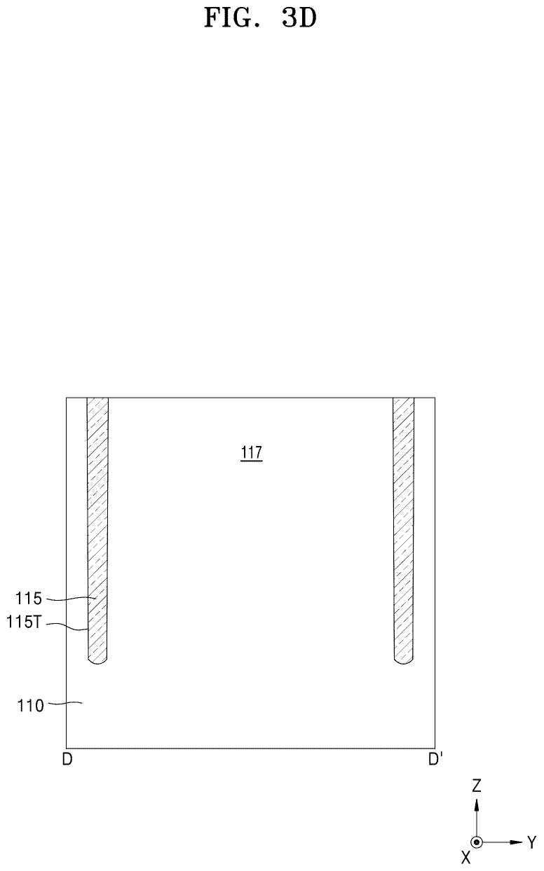

FIGS. 3A to 3D, 4A to 4D, 5A to 5D, 6A to 6D, 7A to 7D, 8A to 8D, and 9A to 9D are cross-sectional views to describe a method of manufacturing a semiconductor device, according to embodiments.

Referring to FIGS. 3A to 3D, a device isolation trench 116T and a logic device isolation trench 115T may be formed in a substrate 110, and a device isolation layer 116 filling the device isolation trench 116T and a logic device isolation layer 115 filling the logic device isolation trench 115T may be formed. In embodiments, the device isolation layer 116 and the logic device isolation layer 115 may be formed together. The device isolation layer 116 may define a plurality of active regions 118, and the logic device isolation layer 115 may define a plurality of logic active regions 117.

Subsequently, a plurality of word line trenches 120T may be formed in the substrate 110. The plurality of word line trenches 120T may extend in parallel in the first horizontal direction (the X direction), and each of the plurality of word line trenches 120T may have a line shape which is arranged to have an equal interval in the second horizontal direction (the Y direction) across the active region 118. In embodiments, a step height may be formed in lower surfaces of the plurality of word line trenches 120T.

Subsequently, the formed plurality of word line trenches 120T may be cleaned, and then, a plurality of word lines 120, including a plurality of gate dielectric layers 122, a lower word line layer 120a, and an upper word line layer 120b, and a plurality of buried insulation layers 124, may be sequentially formed in the plurality of word line trenches 120T.

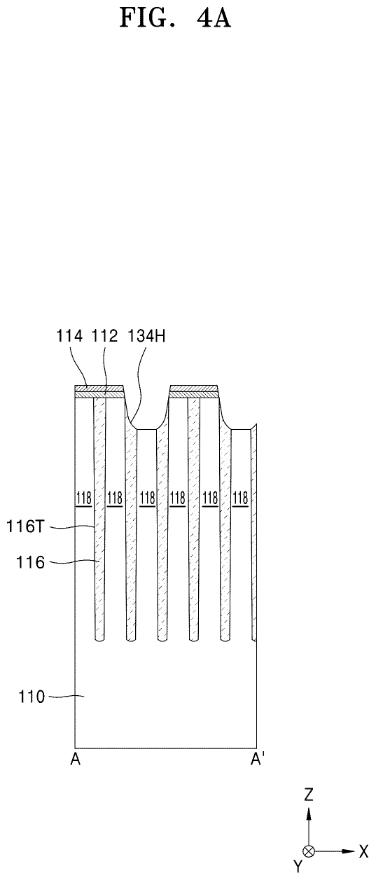

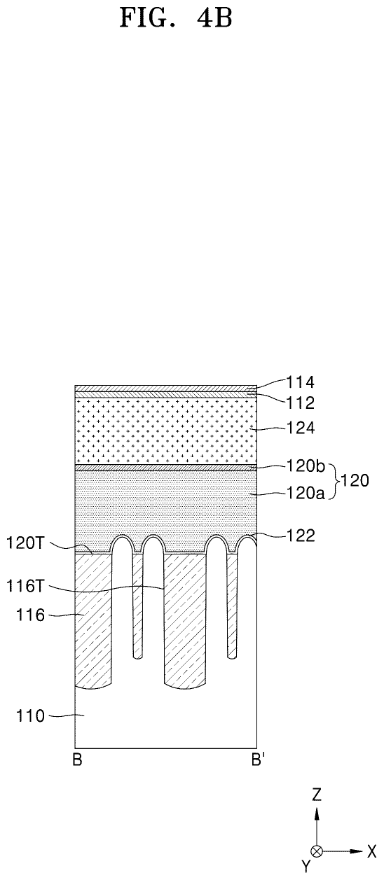

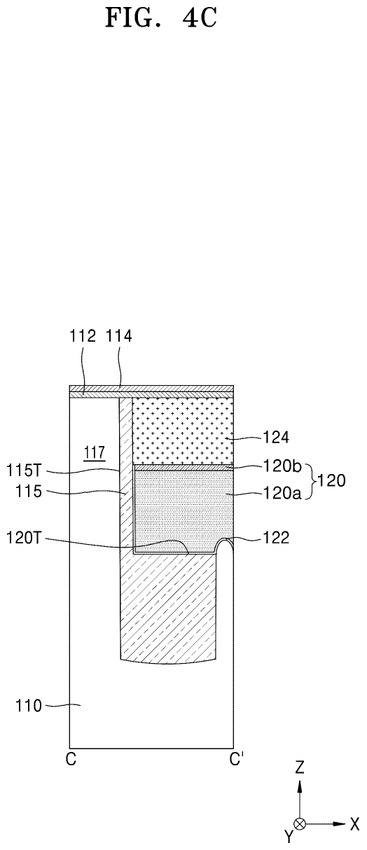

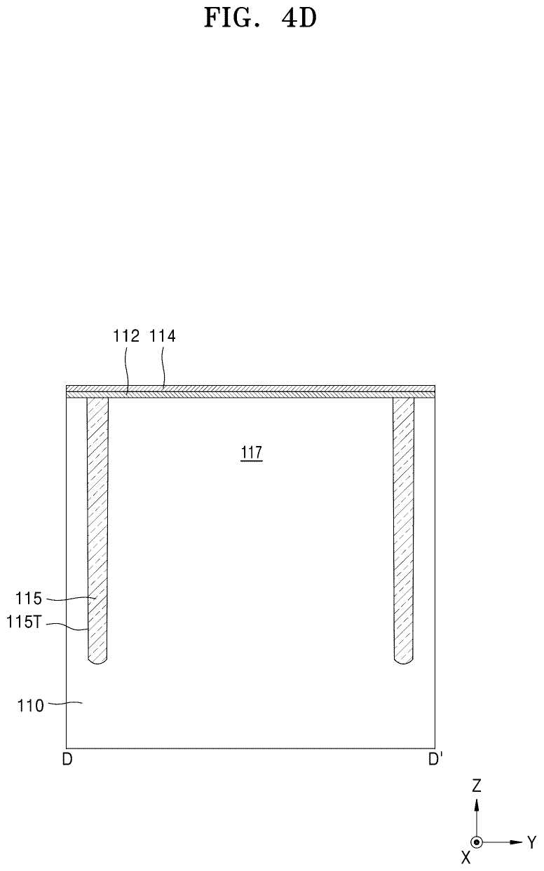

Referring to FIGS. 4A to 4D, a first insulation layer pattern 112 and a second insulation layer pattern 114 each covering the device isolation layer 116, the plurality of active regions 118, the plurality of buried insulation layers 124, the logic device isolation layer 115, and the plurality of logic active regions 117 may be sequentially formed.

Subsequently, a bit line contact hole 134H passing through the first insulation layer pattern 112 and the second insulation layer pattern 114 and extending to an inner portion of the active region 118 may be formed.

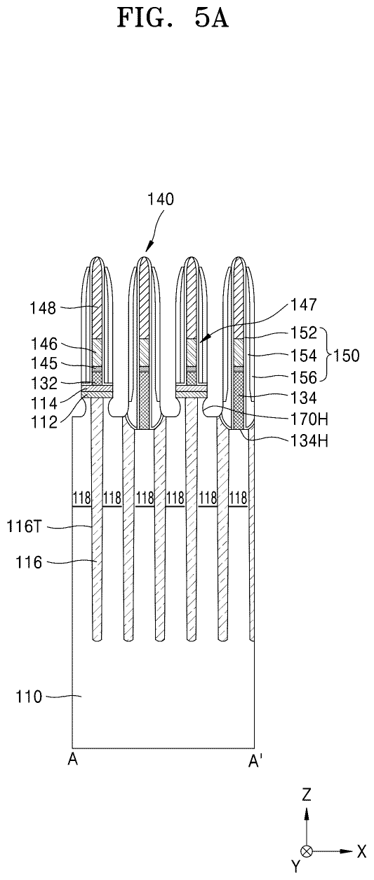

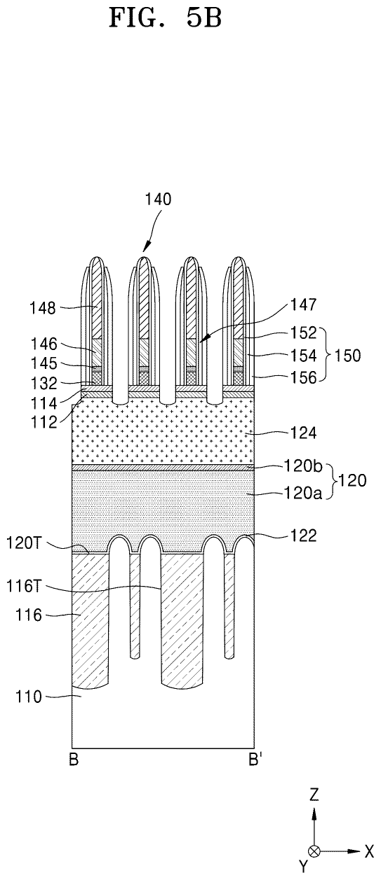

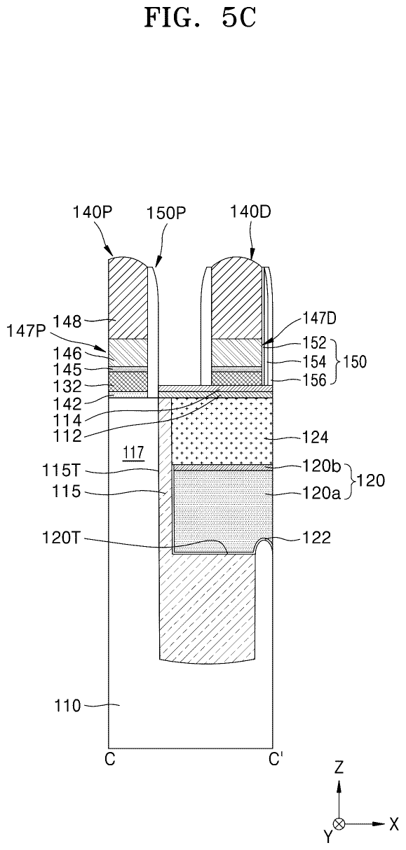

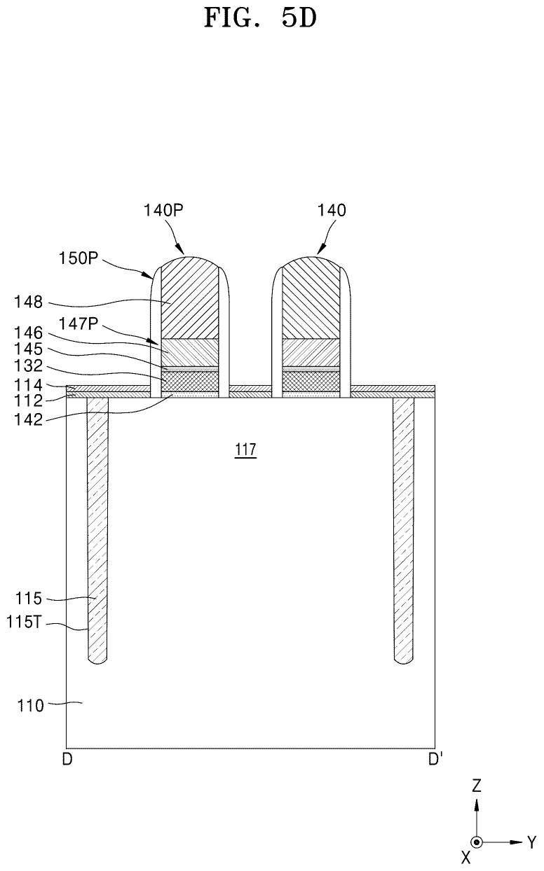

Referring to FIGS. 5A to 5D, a first conductive material layer (not shown) filling the bit line contact hole 134H and covering the first insulation layer pattern 112 and the second insulation layer pattern 114 may be formed on the device isolation layer 116 and the plurality of active regions 118. The first conductive material layer may include, for example, Si, Ge, W, WN, Co, Ni, Al, Mo, Ru, Ti, TiN, Ta, TaN, Cu, or a combination thereof. In embodiments, the first conductive material layer may include an epitaxial silicon layer. In other embodiments, the first conductive material layer may include doped polysilicon. After an etching process to be described below, a portion, filling the bit line contact hole 134H, of the first conductive material layer may configure a bit line contact 134, and a portion, disposed on the bit line contact 134 and the second insulation layer pattern 114, of the first conductive material layer may configure a lower conductive layer 132.

Subsequently, a second conductive material layer, a third conductive material layer, and an insulation capping layer each covering the first and second insulation layer patterns 112 and 114 and the first conductive material layer may be sequentially formed.

Subsequently, a bit line 147 including a lower conductive layer 132, a middle conductive layer 145, and an upper conductive layer 146 and a plurality of insulation capping lines 148 disposed on the bit line 147 may be formed by etching the first conductive material layer, the second conductive material layer, the third conductive material layer, and the insulation capping layer.

Subsequently, a spacer structure 150 covering both sidewalls of each of the plurality of bit lines 147 and the plurality of insulation capping lines 148 may be formed. Each of a plurality of spacer structures 150 may include a first spacer 152, a second spacer 154, and a third spacer 156, which are sequentially formed on the both sidewalls of each of the plurality of bit lines 147 and the plurality of insulation capping lines 148.

Subsequently, a plurality of buried contact holes 170H may be formed between two adjacent bit lines 147 of the plurality of bit lines 147. The plurality of buried contact holes 170H may be formed by removing a portion of each of the first insulation layer pattern 112, the second insulation layer pattern 114, and the active region 118 by using, as an etch mask, the spacer structure 150 covering the both sidewalls of each of the plurality of bit lines 147 and the plurality of insulation capping lines 148.

A plurality of gate line structures 140P including a gate line 147P and an insulation capping line 148 covering the gate line 147P and a dummy bit line structure 140D including a dummy bit line 147D and an insulation capping line 148 covering the dummy bit line 147D may be formed on the logic active region 117. A plurality of gate lines 147P included in the plurality of gate line structures 140P and a dummy bit line 147D included in the dummy bit line structure 140D may be formed along with the plurality of bit lines 147. That is, each of the gate line 147P and the dummy bit line 147D may include a lower conductive layer 132, a middle conductive layer 145, and an upper conductive layer 146.

A sidewall of the gate line structure 140P may be covered by the gate insulation spacer 150P, and a sidewall of the dummy bit line structure 140D may be covered by at least one of the spacer structure 150 and the gate insulation spacer 150P. The gate insulation spacer 150P may be formed along with the spacer structure 150.

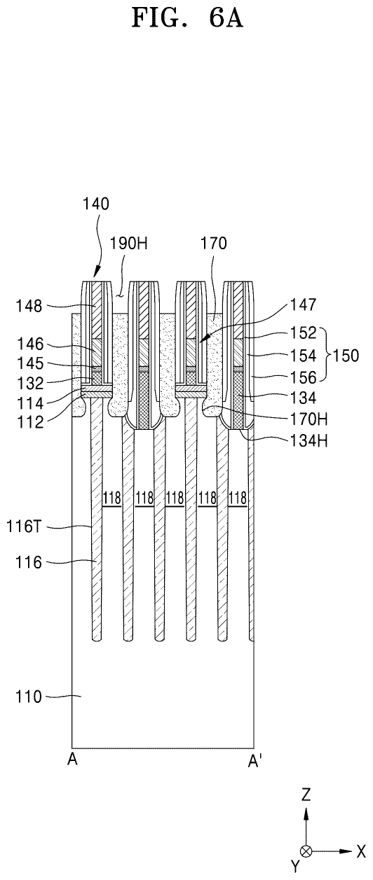

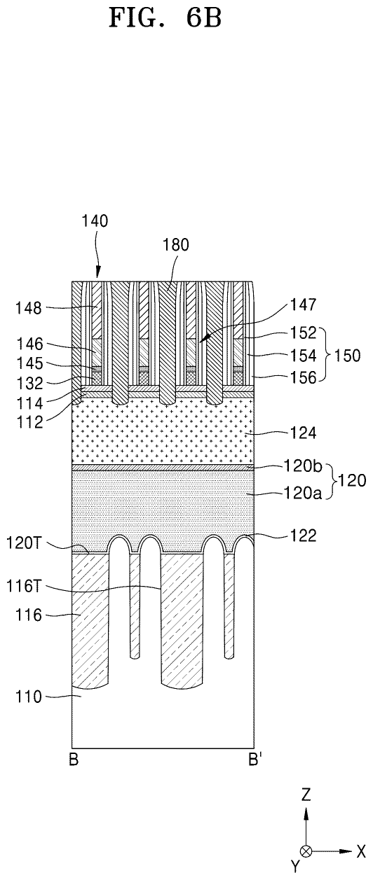

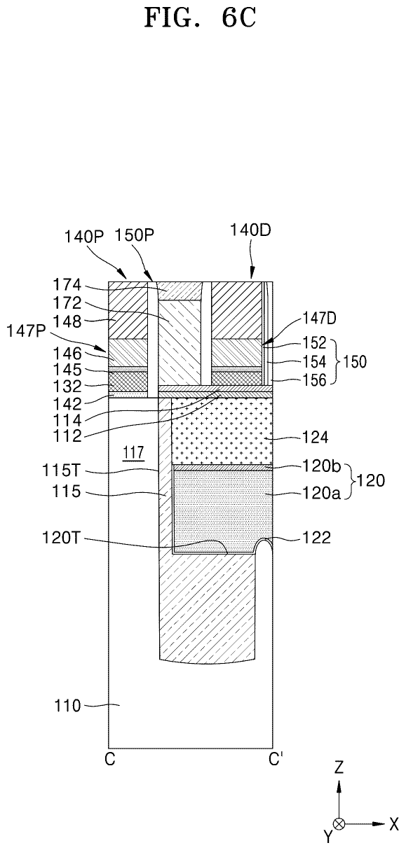

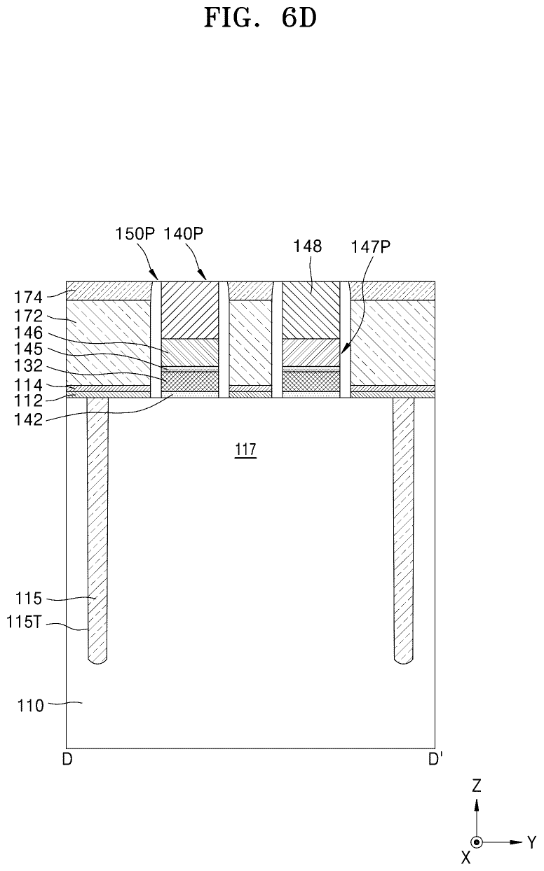

Referring to FIGS. 6A to 6D, a plurality of buried contacts 170 and a plurality of insulation fences 180 may be formed in a space between the plurality of spacer structures 150 covering the both sidewalls of each of the plurality of bit lines 147. A plurality of landing pad holes 190H may be defined by the plurality of spacer structures 150 and the plurality of insulation fences 180. A plurality of buried contacts 170 may be exposed at lower surfaces of the plurality of landing pad holes 190H.

Moreover, a first interlayer insulation layer 172 and a second interlayer insulation layer 174 may be sequentially formed on the first insulation layer pattern 112 and the second insulation layer pattern 114 each adjacent to the plurality of gate line structures 140P, on the logic active region 117.

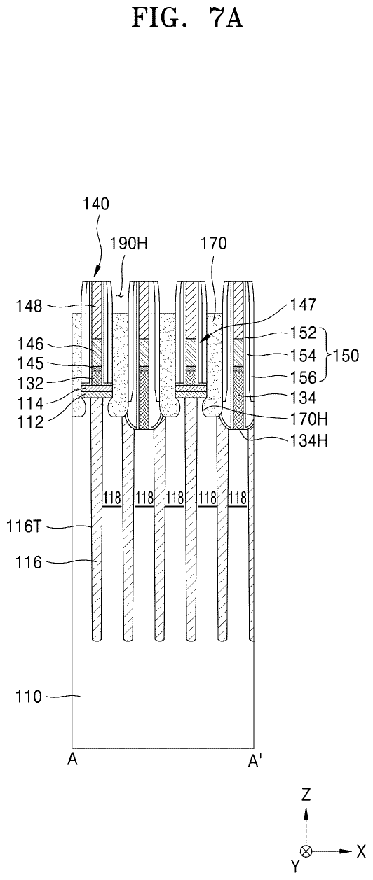

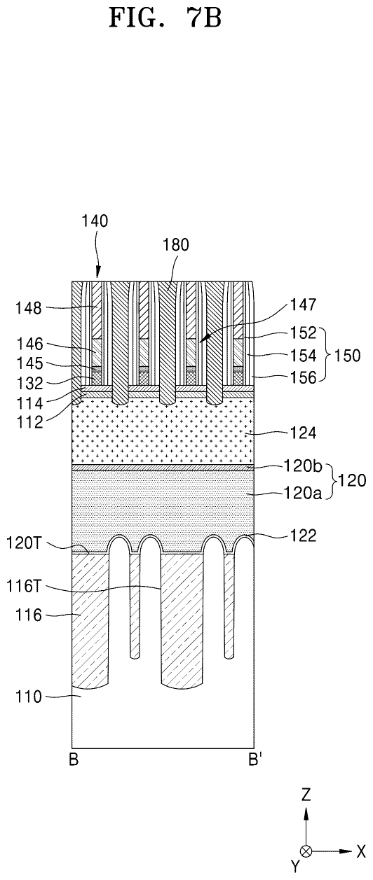

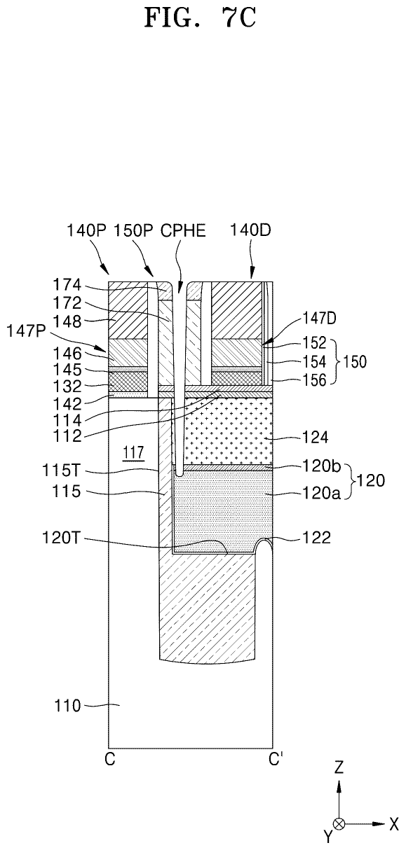

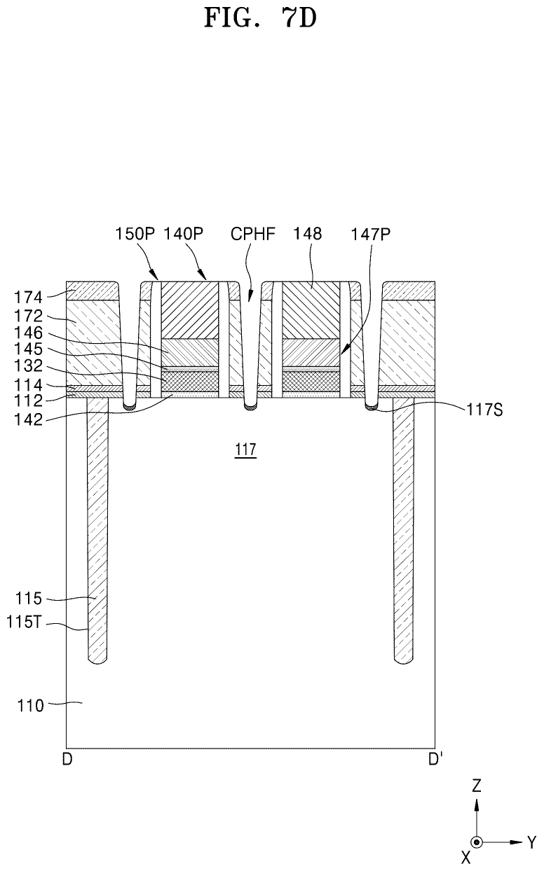

Referring to FIGS. 7A to 7D, a word line contact hole CPHE and a logic active region contact hole CPHF each passing through the first interlayer insulation layer 172, the second interlayer insulation layer 174, the first insulation layer pattern 112, and the second insulation layer pattern 114 may be formed on the logic active region 117.

To provide a detailed description, the word line contact hole CPHE and the logic active region contact hole CPHF each passing through the first interlayer insulation layer 172, the second interlayer insulation layer 174, the first insulation layer pattern 112, and the second insulation layer pattern 114 may be first formed by a first etching gas. The word line contact hole CPHE may extend to an inner portion of the buried insulation layer 124 by using a first etching process, and the logic active region contact hole CPHF may extend to an inner portion of the logic active region 117. After the first etching process is performed, a bottom surface of the word line contact hole CPHE may be disposed at a vertical level which is higher than a bottom surface of the buried insulation layer 124. That is, after the first etching process is performed, the word line contact hole CPHE may not extend to an inner portion of the buried insulation layer 124, or may not pass through the buried insulation layer 124.

The first etching process may use a first etching gas. The first etching gas may include difluoromethane (CH₂F₂) and octafluorobutyne (C₄F₈). In embodiments, a ratio of difluoromethane and octafluorobutyne each included in the first etching gas may be about 1: about 1.5 or more. When a ratio of difluoromethane and octafluorobutyne each included in the first etching gas is about 1:about 1.5 or more, the first etching gas may react with Si included in the logic active region 117 in an etching process using the first etching gas, and thus, a barrier layer 117S may be formed on the logic active region 117 exposed by the logic active region contact hole CPHF. The barrier layer 117S may include fluorocarbon. The barrier layer 117S may cover an exposed upper surface of the logic active region 117. That is, as the barrier layer 117S is formed, the logic active region 117 may not be exposed by the logic active region contact hole CPHF and may be closed.

After the barrier layer 117S is formed, a second etching process may be performed by using a second etching gas having a composition ratio which differs from that of the first etching gas. Based on the second etching process using the second etching gas, the word line contact hole CPHE may pass through the buried insulation layer 124 and may extend to an inner portion of the upper word line layer 120b. On the other hand, in the second etching process using the second etching gas, the logic active region contact hole CPHF may be protected by the barrier layer 117S formed in the first etching process. Therefore, even when the second etching process is performed, the logic active region contact hole CPHF may not extend to an inner portion of the logic active region 117.

In embodiments, the second etching gas may include difluoromethane and octafluorobutyne, and a ratio of difluoromethane and octafluorobutyne each included in the second etching gas may be about 1:about 1.5 or less. When a ratio of difluoromethane and octafluorobutyne each included in the second etching gas is about 1:about 1.5 or more, the second etching gas may react with polysilicon configuring the upper word line layer 120b, based on the second etching process, and thus, a barrier layer may be formed on the upper word line layer 120b exposed by the word line contact hole CPHE extending to an inner portion of the upper word line layer 120b. In this case, the barrier layer formed on the upper word line layer 120b may protect the upper word line layer 120b, and thus, the word line contact hole CPHE may not pass through the upper word line layer 120b and the lower word line layer 120a in a subsequent etching process.

Subsequently, a third etching process may be performed by using a third etching gas having a composition ratio which differs from that of each of the first etching gas and the second etching gas. Based on the third etching process using the third etching gas, the word line contact hole CPHE may pass through the buried insulation layer 124 and the upper word line layer 120b and may extend to an inner portion of the lower word line layer 120a. On the other hand, in the third etching process using the third etching gas, the logic active region contact hole CPHF may be protected by the barrier layer 117S formed in the first etching process. Therefore, the logic active region contact hole CPHF may not extend to the inner portion of the logic active region 117 in the third etching process.

In embodiments, the third etching gas may include difluoromethane and octafluorobutyne, and a ratio of difluoromethane and octafluorobutyne each included in the third etching gas may be about 1:about 1.5 or less. When a ratio of difluoromethane and octafluorobutyne each included in the third etching gas is about 1:about 1.5 or more, the third etching gas may react with polysilicon configuring the upper word line layer 120b, based on the third etching process, and thus, a barrier layer may be formed on the upper word line layer 120b exposed by the word line contact hole CPHE extending to an inner portion of the upper word line layer 120b. In this case, the barrier layer formed on the upper word line layer 120b may protect the upper word line layer 120b, and thus, the word line contact hole CPHE may not pass through the upper word line layer 120b and the lower word line layer 120a in the third etching process.

In embodiments, the third etching process may be omitted. In this case, based on the second etching process using the second etching gas, the word line contact hole CPHE may pass through the buried insulation layer 124 and the upper word line layer 120b and may extend to the inner portion of the lower word line layer 120a.

Subsequently, the word line contact hole CPHE and the logic active region contact hole CPHF may be cleaned. In such a cleaning process, barrier layers 117S formed on the logic active region 117 may be removed.

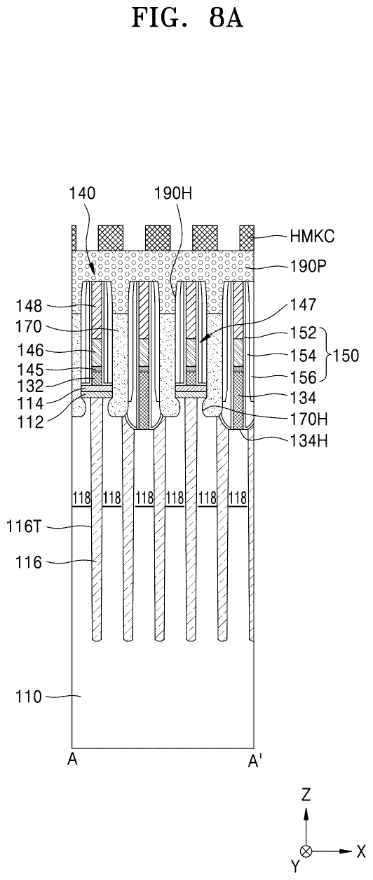

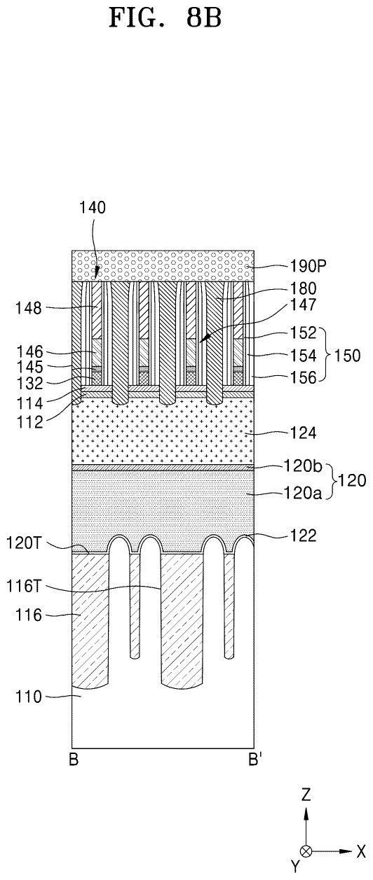

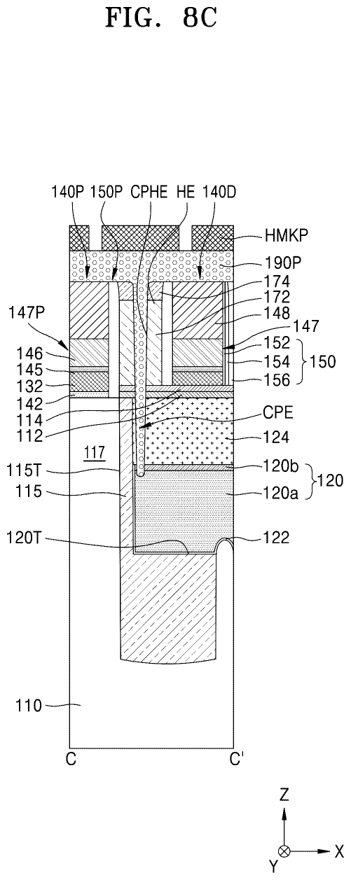

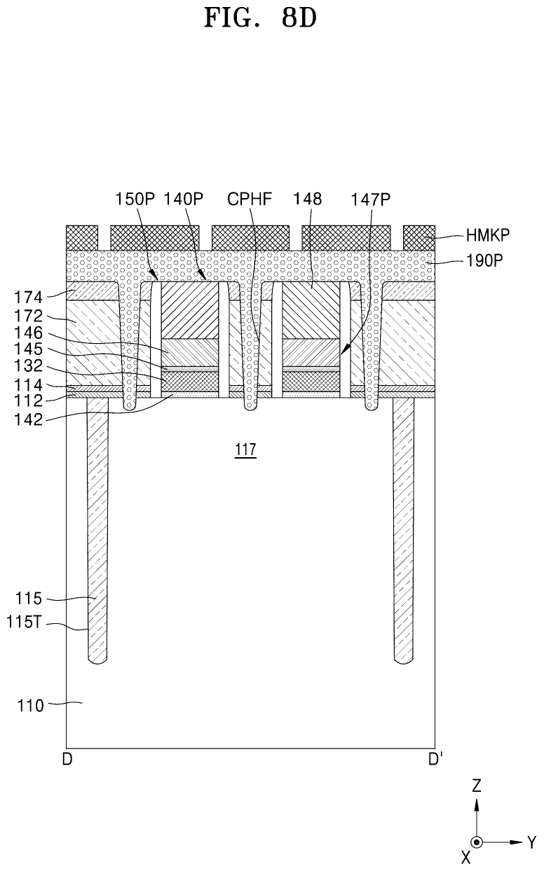

Referring to FIGS. 8A to 8D, a landing pad material layer 190P filling the plurality of landing pad holes 190H, the word line contact hole CPHE, and the logic active region contact hole CPHF and covering the plurality of bit lines 147, the plurality of gate line structures 140P, and at least one dummy bit line structure 140D may be formed.

Subsequently, a plurality of hard mask patterns HMKC and HMKP may be formed on the landing pad material layer 190P. In embodiments, the plurality of hard mask patterns HMKC and HMKP may be formed through an extreme ultraviolet (EUV) lithography process. The plurality of hard mask patterns HMKC and HMKP may include a cell hard mask pattern HMKC, disposed on the plurality of landing pad holes 190H and a portion of the landing pad material layer 190P adjacent to the plurality of landing pad holes 190H, and a logic hard mask pattern HMKP disposed on the word line contact hole CPHE, the logic active region contact hole CPHF, and another portion of the landing pad material layer 190P adjacent to the word line contact hole CPHE and the logic active region contact hole CPHF.

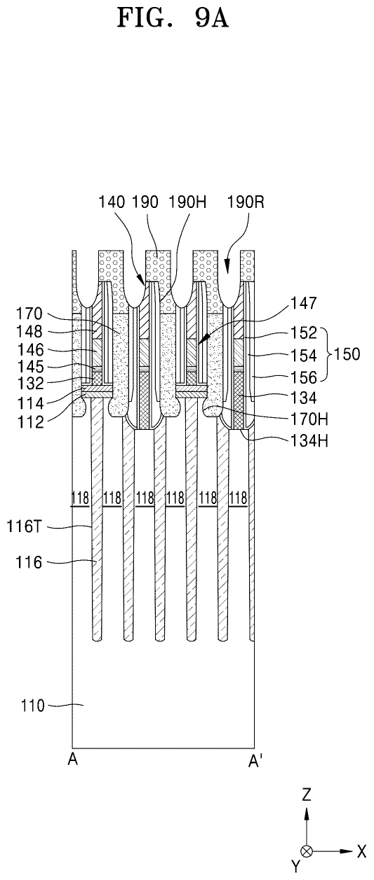

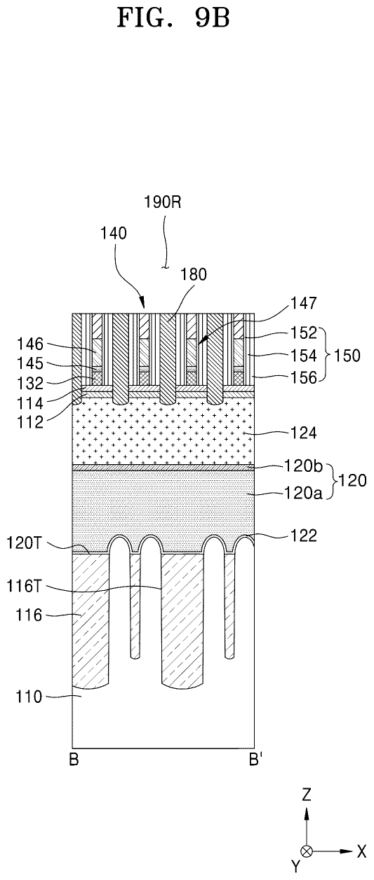

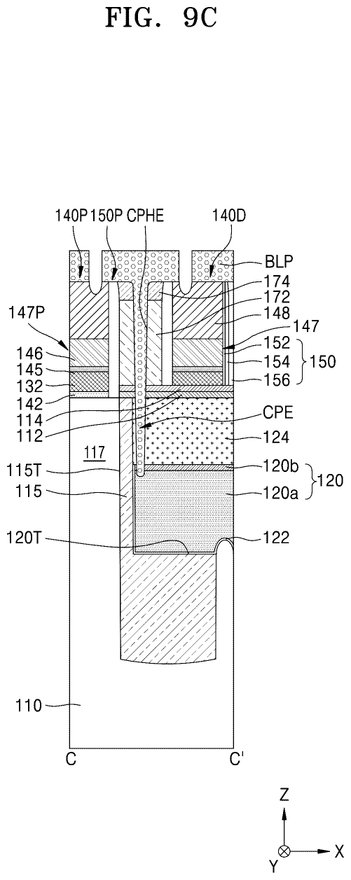

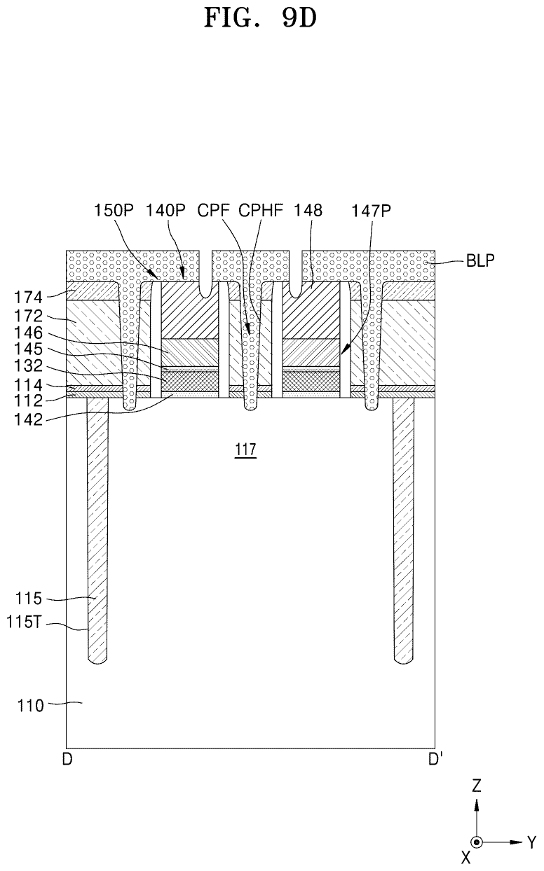

Referring to FIGS. 9A to 9D, by removing the plurality of landing pad holes 190H and a portion of the landing pad material layer 190P (see FIGS. 8A to 8D) adjacent to the plurality of landing pad holes 190H by using the cell hard mask pattern HMKC as an etch mask, at least a portion of each of the plurality of landing pad holes 190H may be filled and may extend onto the plurality of bit lines 147, and a plurality of landing pads 190 divided by the recess portion 190R may be formed.

Subsequently, a plurality of logic bit lines BLP, and a word line contact plug CPE and a logic active region contact plug CPF respectively filling the word line contact hole CPHE and the logic active region contact hole CPHF may be formed by removing the word line contact hole CPHE, the logic active region contact hole CPHF, and a portion of the landing pad material layer 190P adjacent to the word line contact hole CPHE and the logic active region contact hole CPHF by using the logic hard mask pattern HMKP as an etch mask.

The plurality of landing pads 190, the plurality of logic bit lines BLP, the word line contact plug CPE, and the logic active region contact plug CPF may be simultaneously formed by the same etching process using both the cell hard mask pattern HMKC and the logic hard mask pattern HMKP as an etch mask.

Subsequently, in a resultant material of FIGS. 9A and 9B, a plurality of lower electrodes 210, a capacitor dielectric layer 220, and an upper electrode 230 may be sequentially formed on the plurality of landing pads 190, and thus, a semiconductor memory device 100 (see FIGS. 2A to 2D) including a plurality of capacitor structures 200 may be formed.

Moreover, a buried insulation layer 250 may be filled on the plurality of logic bit lines BLP corresponding to a vertical level at which the plurality of capacitor structures 200 are disposed.

A method of manufacturing the semiconductor device 100 according to embodiments may perform the first etching process by using the first etching gas which includes difluoromethane and octafluorobutyne and where a ratio of difluoromethane to octafluorobutyne is about 1: about 1.5 or more, and then, may perform subsequent etching processes to form the word line contact hole CPHE and the logic active region contact hole CPHF. At this time, the first etching gas may react with Si configuring the logic active region 117 in the first etching process, and thus, a barrier layer 117S may be formed on the logic active region 117 exposed by the logic active region contact hole CPHF. Because the barrier layer 117S protects the logic active region 117, over-etching of the logic active region 117 may be limited and/or prevented when performing a subsequent etching process, thereby limiting and/or preventing an excessive increase in the critical dimension of the logic active region contact hole CPHF and the depth of the logic active region contact hole CPHF in a vertical direction (a Z direction).

Hereinabove, embodiments have been described in the drawings and the specification. Embodiments have been described by using the terms described herein, but this has been merely used for describing inventive concepts and has not been used for limiting a meaning or limiting the scope of inventive concepts defined in the following claims. Therefore, it may be understood by those of ordinary skill in the art that various modifications and other equivalent embodiments may be implemented from inventive concepts. Accordingly, the spirit and scope of inventive concepts may be defined based on the spirit and scope of the following claims.

While inventive concepts have been particularly shown and described with reference to the presented embodiments, it will be understood that various changes in form and details may be made therein without departing from the spirit and scope of inventive concepts in the following claims.

What is claimed is:

1. A method of manufacturing a semiconductor device, the method comprising:
sequentially forming a word line filling a word line trench of a substrate and a buried insulation layer on the word line;
performing a first etching process,
the first etching process including forming a logic active region contact hole extending to an inner portion of a logic active region of the substrate and forming a word line contact hole extending to an inner portion of the buried insulation layer; and
performing a second etching process so that the word line contact hole passes through the buried insulation layer and extends to an inner portion of the word line, wherein
the first etching process is performed using a first etching gas,
the first etching gas includes difluoromethane (CH₂F₂) and octafluorobutyne (C₄F₈), where a ratio of difluoromethane to octafluorobutyne in the first etching gas is at least 1:1.5, and
the logic active region contact hole exposes the logic active region of the substrate to provide an exposed logic active region of the substrate, and
the first etching process includes forming a barrier layer on the exposed logic active region of the substrate, the barrier layer being formed from the first etching gas reacting with a material of the substrate in the logic active region of the substrate that is exposed by the logic active region contact hole while the first etching process is performed.

2. The method of claim 1, wherein the barrier layer covers an upper surface of the exposed logic active region of the substrate.

3. The method of claim 1, wherein the barrier layer comprises fluorocarbon.

4. The method of claim 1, wherein
the second etching process is performed using a second etching gas,
the second etching gas includes difluoromethane and octafluorobutyne, and
a ratio of difluoromethane to octafluorobutyne in the second etching gas is 1:1.5 or less.

5. The method of claim 1, wherein
after the performing the first etching process, a vertical level of a bottom surface of the word line contact hole is higher than a bottom surface of the buried insulation layer.

6. The method of claim 1, wherein the barrier layer is configured to protect the logic active region from the second etching process.

7. A method of manufacturing a semiconductor device, the method comprising:
sequentially forming a word line filling a word line trench of a substrate and a buried insulation layer on the word line, the word line including an upper word line layer and a lower word line layer;
performing a first etching process,
the first etching process including forming a logic active region contact hole extending to an inner portion of a logic active region of the substrate and a word line contact hole extending to an inner portion of the buried insulation layer;
performing a second etching process so that the word line contact hole passes through the buried insulation layer and extends to an inner portion of the upper word line layer; and
performing a third etching process so that the word line contact hole passes through the upper word line layer and extends to an inner portion of the lower word line layer, wherein
the first etching process is performed using a first etching gas,
the first etching gas includes difluoromethane (CH₂F₂) and octafluorobutyne (C₄F₈), where a ratio of difluoromethane to octafluorobutyne in the first etching gas is at least 1:1.5,
the logic active region contact hole exposes the logic active region of the substrate to provide an exposed logic active region of the substrate, and
the first etching process includes forming a barrier layer on the exposed logic active region of the substrate, the barrier layer being formed from the first etching gas reacting with a material of the substrate in the logic active region of the substrate that is exposed by the logic active region contact hole while the first etching process is being performed.

8. The method of claim 7, wherein
the barrier layer covers an upper surface of the exposed logic active region of the substrate, and
the barrier layer comprises fluorocarbon.

9. The method of claim 7, wherein
after the performing the first etching process, a bottom surface of the word line contact hole is higher than a bottom surface of the buried insulation layer.

10. The method of claim 7, wherein
the second etching process is performed using a second etching gas,
the second etching gas includes difluoromethane and octafluorobutyne, and
a ratio of difluoromethane to octafluorobutyne in the second etching gas is 1:1.5 or less.

11. The method of claim 10, wherein
the upper word line layer comprises polysilicon and
the second etching gas does not form a barrier layer from the polysilicon in the upper word line layer during the second etching process.

12. The method of claim 10, wherein
the third etching process is performed using a third etching gas,
the third etching gas comprises difluoromethane and octafluorobutyne,
a ratio of difluoromethane to octafluorobutyne in the third etching gas is 1:1.5 or less, and
the ratio of difluoromethane and octafluorobutyne in the third etching gas differs from the ratio of difluoromethane and octafluorobutyne in the second etching gas.

13. The method of claim 7, wherein the barrier layer is configured to protect the exposed logic active region from the second etching process.

14. The method of claim 7, further comprising:
cleaning the logic active region contact hole and the word line contact hole after the third etching process is performed,
wherein the barrier layer is removed by the cleaning.

15. The method of claim 14, further comprising forming:
a logic active region contact plug filling the logic active region contact hole after the cleaning,
wherein the logic active region contact plug contacts the logic active region.

16. The method of claim 14, further comprising forming:
a word line contact plug filling the word line contact hole after the cleaning,
wherein the word line contact plug contacts the upper word line layer and the lower word line layer.

17. A method of manufacturing a semiconductor device, the method comprising:
sequentially forming a word line filling a word line trench of a substrate and a buried insulation layer on the word line, the word line including an upper word line layer and a lower word line layer;
forming a plurality of bit line contact holes extending to an inner portion of an active region of the substrate;
forming a plurality of bit line structures respectively filling the plurality of bit line contact holes;
forming a spacer structure covering a sidewall of each of the plurality of bit line structures;
forming a buried contact hole between two adjacent bit line structures of the plurality of bit line structures such that a plurality of buried contact holes are formed, the plurality of buried contact holes being defined by the spacer structure and upper surfaces of the plurality of active regions;
forming a plurality of buried contacts filling the plurality of buried contact holes;
forming a plurality of insulation fences between the spacer structure and the plurality of buried contacts;
forming a logic active region contact hole extending to an inner portion of a logic active region of the substrate and a word line contact hole passing through the buried insulation layer and extending to an inner portion of the word line;
forming a logic active region contact plug filling the logic active region contact hole, a word line contact plug filling the word line contact hole, and a landing pad filling a landing pad hole defined by the spacer structure and a corresponding insulation fence among the plurality of insulating fences; and
forming a capacitor structure on the landing pad,
wherein the forming the logic active region contact hole and the word line contact hole includes
performing a first etching process including forming a logic active region contact hole extending to an inner portion of a logic active region of the substrate and a word line contact hole extending to an inner portion of the buried insulation layer,
performing a second etching process so that the word line contact hole passes through the buried insulation layer and extends to an inner portion of the upper word line layer, and
performing a third etching process so that the word line contact hole passes through the upper word line layer and extends to an inner portion of the lower word line layer,
the first etching process is performed using a first etching gas,
the first etching gas includes difluoromethane (CH₂F₂) and octafluorobutyne (C₄F₈), where a ratio of difluoromethane to octafluorobutyne is at least 1:1.5,
the logic active region contact hole exposes the logic active region of the substrate to provide an exposed logic active region of the substrate, and
the first etching process includes forming a barrier layer on the exposed logic active region of the substrate, the barrier layer being formed from the first etching gas reacting with a material of the substrate in the logic active region that is exposed by the logic active region contact hole while the first etching process is being performed.

18. The method of claim 17, wherein
the barrier layer covers an upper surface of the exposed logic active region, and
the barrier layer comprises fluorocarbon.

19. The method of claim 17, wherein
the second etching process is performed using a second etching gas,
the second etching gas comprises difluoromethane and octafluorobutyne,
a ratio of difluoromethane to octafluorobutyne in the second etching gas is 1:1.5 or less,
the third etching process is performed using a third etching gas, the third etching gas comprises difluoromethane and octafluorobutyne,
a ratio of difluoromethane to octafluorobutyne in the third etching gas is 1:1.5 or less, and
the ratio of difluoromethane and octafluorobutyne in the third etching gas differs from the ratio of difluoromethane and octafluorobutyne of the second etching gas.

20. The method of claim 17, further comprising:
cleaning the logic active region contact hole and the word line contact hole after the third etching process is performed,
wherein the barrier layer is removed by the cleaning.
